(19) United States
(12) Patent Application Publication
(10) Pub. No.: US 2006/0269691 A1
(43) Pub. Date: Nov. 30, 2006

(54) Plasma treatment apparatus and plasma treatment method

(76) Inventor: Kazuo Saki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/259,050

(22) Filed: Oct. 27, 2005

(30) Foreign Application Priority Data
May 31, 2005 (JP) P2005-159631

(51) Int. Cl. H05H 1/24; C23C 16/00; B05C 11/00

(52) U.S. Cl. 427/569; 118/663; 118/723 R

(57) ABSTRACT

A plasma treatment apparatus includes a susceptor, a silica cover covering a plasma generating area above the susceptor, a chamber housing the susceptor and the silica cover, a gas inlet introducing conditioning gas into the chamber, a plasma generator generating a plasma of the conditioning gas configured to perform conditioning of the silica cover, an analyzing unit configured to monitor changes in a nitride layer on the surface of the silica cover, and a control unit connected to the analyzing unit configured to determine completion of the conditioning based on the change in the nitride layer.

### CROSS REFERENCE TO RELATED APPLICATIONS AND INCORPORATION BY REFERENCE

This application is based upon and claims the benefit of priority from the prior Japanese Patent Applications No. P2005-159631, filed on May 31, 2005; the entire contents of which are incorporated herein by reference.

### BACKGROUND OF THE INVENTION

1. Field of the Invention

The present invention relates to a plasma treatment apparatus used in the fabrication of various semiconductor electronic devices. More specifically, it relates to a plasma treatment apparatus capable of continuous lot processing by carrying out a pretreatment for the plasma treatment, so as to suppress changes in the rate of film formation in the plasma treatment, and a plasma treatment method for applying the pretreatment.

2. Description of the Related Art

In recent years, a plasma treatment, such as a plasma oxidizing process or a plasma nitriding process has been put to practical use for providing a high-quality gate insulating film. The plasma oxidizing process is characterized by providing a higher resistance to electrical stress than an oxide film formed by using a thermal oxidation method of earlier technology. The plasma nitriding process is characterized in that a lower composition of nitride, which is a contributing factor in degeneration of interface characteristics of gate insulating films, in the vicinity of the interface, compared to a nitriding method through thermal nitriding of earlier technology. This is a reason for employing the plasma oxidizing process and the plasma nitriding process.

Since the plasma oxidizing process and the plasma nitriding process can be carried out by the same apparatus, the two processes are carried out by a single apparatus, so as to improve the utilization rate of the apparatus. However, when the plasma nitriding process and the plasma oxidizing process are carried out by the same apparatus, there is a problem in that the film forming rate changes when performing a plasma oxidizing process after plasma nitriding or performing a plasma nitriding process after a plasma oxidizing process.

### BRIEF SUMMARY OF THE INVENTION

An aspect of the present invention inheres in a plasma treatment apparatus including: a susceptor; a silica cover covering a plasma generation area located above the susceptor; a chamber housing the susceptor and the silica cover; a gas inlet configured to introduce a conditioning gas into the chamber; a plasma generator configured to generate a plasma of the conditioning gas, and provide a conditioning treatment to the silica cover; an analyzing unit configured to monitor changes in a nitride layer on the surface of the silica cover; and a control unit connected to the analyzing unit, and configured to determine completion of the conditioning treatment, based on the changes in the nitride layer.

Another aspect of the present invention inheres in a plasma treatment method including conditioning, the conditioning including: introducing conditioning gas into a chamber housing a susceptor and a silica cover covering a plasma generation area located above the susceptor; generating a plasma of the conditioning gas by electric discharge for conditioning the silica cover; monitoring changes in a nitride layer on the surface of the silica cover, based on radicals in the plasma; and determining completion of the conditioning, based on the change in the monitored nitride layer.

### BRIEF DESCRIPTION OF THE DRAWINGS

FIG. 1 is a schematic diagram of a plasma treatment apparatus according to a first embodiment;

FIG. 2 is a flowchart according to a nitriding conditioning method according to the first embodiment;

FIG. 3 is a schematic diagram describing measurement of a nitride layer in a silica portion of the plasma treatment apparatus according to the first embodiment (1 of 2);

FIG. 4 is a graph showing the nitrogen compositions of the nitride layer formed on an untreated substrate in the plasma treatment apparatus according to the first embodiment;

FIG. 5 is a flowchart according to a denitrification conditioning method according to the first embodiment;

FIG. 6 is a schematic diagram describing measurement of a nitride layer in a silica portion of the plasma treatment apparatus according to the first embodiment (2 of 2);

FIG. 7 is a graph showing the film thicknesses of an oxide film formed on the untreated substrate in the plasma treatment apparatus according to the first embodiment;

FIG. 8 is a schematic diagram of a plasma treatment apparatus according to a second embodiment;

FIG. 9 is a schematic diagram describing measurement of a nitride layer in a silica portion of the plasma treatment apparatus according to the second embodiment;

FIG. 10 is another schematic diagram describing measurement of a nitride layer in a silica portion of the plasma treatment apparatus according to the second embodiment; and

FIG. 11 is a schematic diagram of a plasma treatment apparatus according to a third embodiment.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Note that a semiconductor fabrication apparatus is described below as merely an example, and the present invention may naturally apply to fabrication of various electronic devices such as a liquid crystal display, a magnetic storage medium, or a superconducting element aside from a semiconductor device.

### COMPARATIVE EXAMPLE

When a plasma nitriding process and a plasma oxidizing process are carried out by the same apparatus, a film formation rate of plasma oxidizing changes after plasma nitriding or a film formation rate of plasma nitriding changes after plasma oxidizing.

The change in the film formation rate depends on whether or not oxynitride (SiON) exists in a silica portion (SiO₂), provided in a metal chamber, for preventing metal contamination emanating from the chamber or from a microwave antenna when carrying out plasma treatment, such as a plasma oxidizing process or a plasma nitriding process (‘oxynitride’ is simply abbreviated as ‘nitride’ hereafter). For example, in the case of carrying out the plasma oxidizing process when nitride exists on the silica surface, the nitride detaches from the silica surface during plasma oxidizing, and the detached nitrogen or nitrogen activated species controls the oxidizing rate. On the other hand, in the case of carrying out the plasma oxidizing process when there is no nitride on the silica surface, since nitrided species are consumed by the silica during the plasma nitriding process, thereby controlling the nitriding rate on an actual silicon substrate, the nitrogen composition in the film is reduced, and film quality deteriorates.

Accordingly, conditioning of the chamber or so is carried out as a pretreatment so as to changes the film formation rate and provide a uniform plasma treatment, such as a plasma oxidizing process after plasma nitriding, or a plasma nitriding process. Nitriding conditioning is carried out before plasma nitriding for pre-formation of a nitride layer on the silica surface in the chamber. A denitrification conditioning is conducted prior to plasma oxidizing to make the nitrogen detach from the nitride layer of the silica surface. In other words, the conditioning suppresses changes in the film formation rate during the plasma oxidizing process and the plasma nitriding process; however, conditioning is expensive and takes time and therefore substantially reduces throughput, leading to a decrease in productivity.

### First Embodiment

(Plasma Treatment Apparatus)

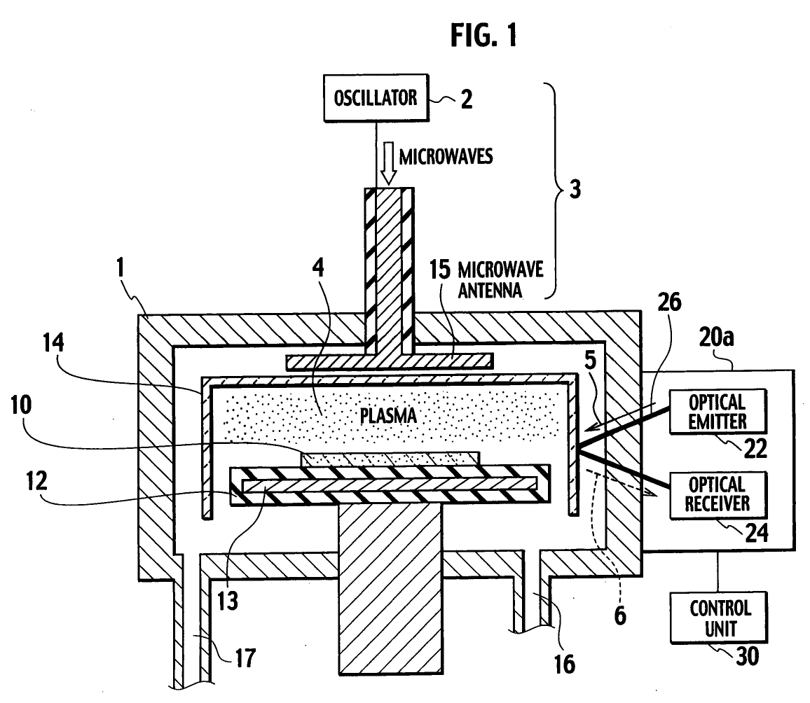

A plasma treatment apparatus according to the first embodiment is a semiconductor fabrication apparatus capable of carrying out plasma nitriding and plasma oxidizing. The plasma treatment apparatus according to the first embodiment, as shown in FIG. 1, comprises a susceptor 12, a silica portion (hereinafter, also referred to as a “cover”) 14, which covers an area above the susceptor 12 where plasma is generated, a chamber 1, which houses the susceptor 12 and the silica portion or cover 14, a gas inlet 16, which introduces conditioning gas into the chamber 1, a plasma generator 3, which generates a plasma 4 from the conditioning gas by discharging microwaves and carries out conditioning for the silica portion 14, an analyzing unit 20a, which is arranged outside of the chamber 1 and monitors changes in a nitride layer on the surface of the silica portion or cover 14, and a control unit 30 connected to the analyzing unit 20a and determines whether the conditioning has been completed, based on the changes in the nitride layer. The plasma generator 3 includes an oscillator 2 configured to generate microwaves, and a microwave antenna 15 configured to emit the microwaves. In addition, the plasma treatment apparatus is configured to places an untreated substrate 10 on the susceptor after the conditioning is completed, and then carries out a plasma treatment of the surface of the untreated substrate 10. Here, a semiconductor substrate may be the ‘untreated substrate’ in the case of a semiconductor fabrication apparatus. However, the untreated substrate may be a resin substrate in the case of a magnetic storage medium, and may be any of various materials including a superconductive material substrate in the case of a superconductive element, such as a Josephson device. Furthermore, the untreated substrate 10 may be a semiconductor substrate provided first as a raw material by a substrate manufacturer. As the fabrication procedure progresses, a film or the like is newly formed on the surface of the substrate, changing the substrate to a ‘new untreated substrate’, which is then defined as a target substrate to be subjected to a treatment. Moreover, ‘plasma treatment’ denotes a treatment utilizing a plasma chemical reaction of forming an oxide film or a nitride film on the untreated substrate 10 through a plasma oxidizing process or a plasma nitriding process.

The chamber 1 is a furnace having a sealed structure capable of off external air and maintaining an internal atmosphere. The chamber 1 is provided with the gas inlet 16, which introduces a conditioning gas into the chamber 1, and an exhaust line 17, which exhausts the conditioning gas from the chamber 1. The conditioning gas may be a mixture of argon (Ar) and helium (He) needed for facilitating plasma excitation, and nitrogen (N₂) and oxygen (O₂) that will be used for conditioning. The susceptor 12 comprises a resistor heater 13 made of ceramics, an aluminum alloy, or the like. The silica cover 14 prevents metal contamination from the microwave antenna 15 or the walls of the chamber 1 as it does not easily chemically react with an active gas. The exhaust line 17 is connected to a vacuum pump and maintains a vacuum (low-pressure) state of approximately 20 to 200 Pa, for example, in the chamber 1.

The analyzing unit 20a comprises an optical emitter 22 configured to emit a single-wavelength laser beam 5, and an optical receiver 24 configured to receive a reflected light 6 of the laser beam 5 reflected from the silica cover 14. The laser beam 5, emitted from the optical emitter 22, is transmitted to the cover 14 via an optical transmission line 26, such as a light-transmitting optical fiber. The analyzing unit 20a measures refractive index by monitoring the wave 6 reflected from the silica portion 14 and received by the optical receiver 24. Measuring changes in the refractive index allows monitoring of changes in the thickness of the nitride layer generated on the surface of the silica portion or cover 14. Results of the analyzing unit 20a are transmitted as a signal to the control unit 30. The control unit 30 determines completion of conditioning when the thickness of the nitride layer on the cover 14 is processed to a desired thickness, in response to the signal transmitted from the analyzing unit 20a.

According to the first embodiment, a plasma treatment apparatus capable of suppressing changes in a film formation rate and film quality during plasma treatment is provided. The apparatus decreases expense and time on pretreatment conditioning.

(Nitriding Conditioning Method)

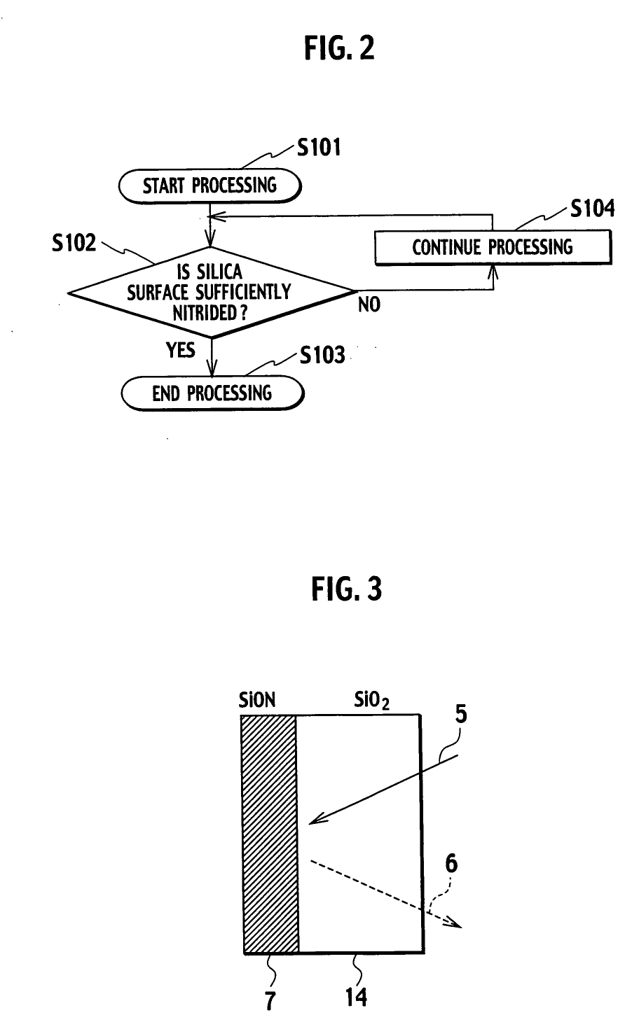

A nitriding conditioning method for continuous lot processing of substrates, such as a plasma oxidizing process for a first lot, and then a plasma nitriding process for the next lot of substrates, using the plasma treatment apparatus of the first embodiment, is described forthwith while referencing the flowchart of FIG. 2. ‘Nitriding conditioning’ is a conditioning process for forming a nitride layer on the silica cover before the plasma nitriding process, which forms a plasma nitride film on the untreated substrate 10.

Firstly, in step S101, a conditioning gas for nitriding conditioning is introduced from the gas inlet 16 in order to form a nitride layer on the surface of the silica cover 14 in the chamber 1. Ar gas and N₂ gas are simultaneously introduced into the chamber as the conditioning gas. Gas flow rates of the Ar gas and the N₂ gas are set to 1000 sccm and 50 sccm, respectively. Once the gas flow rates have stabilized, microwaves are generated from the microwave antenna 15 and then discharged, generating nitrogen radicals (N*). The silica cover 14 is then subjected to nitriding conditioning using the nitrogen radicals. In this case, the internal pressure of the chamber 1 is set to 130 Pa, and the microwave power is set to 1.0 kW.

While carrying out the nitriding conditioning, the thickness of the nitride layer on the surface of the silica cover 14 is simultaneously monitored. The monitoring method for the nitride layer 7 includes measuring the refractive index by exposing the single-wavelength light 5 on the silica cover 14, in the chamber 1, and monitoring the reflected light wave 6 with the analyzing unit 20a, as shown in FIG. 3. Measuring changes in the refractive index allows monitoring of changes in thickness of the nitride layer 7 generated on the surface of the silica cover 14.

In step S102, whether the nitriding conditioning has been carried out long enough for the nitride layer 7 to have a desired thickness is determined. The desired thickness of the nitride layer 7 is 20 nm, for example. A signal indicating the thickness of the nitride layer 7 is sent to the control unit 30 from the analyzing unit 20a. The control unit 30 determines that the nitride layer 7 is formed with the desired thickness and processing proceeds to step S103, completing the nitriding conditioning. When the control unit determines that the nitride layer 7 is not formed with the desired thickness, processing proceeds to step S104, and nitriding conditioning is continued.

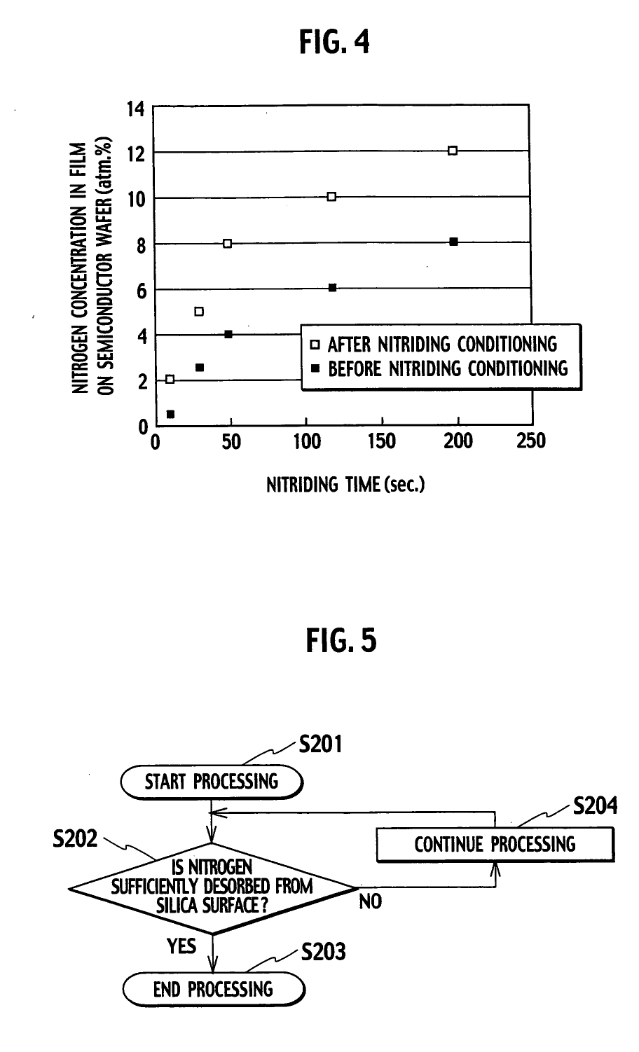

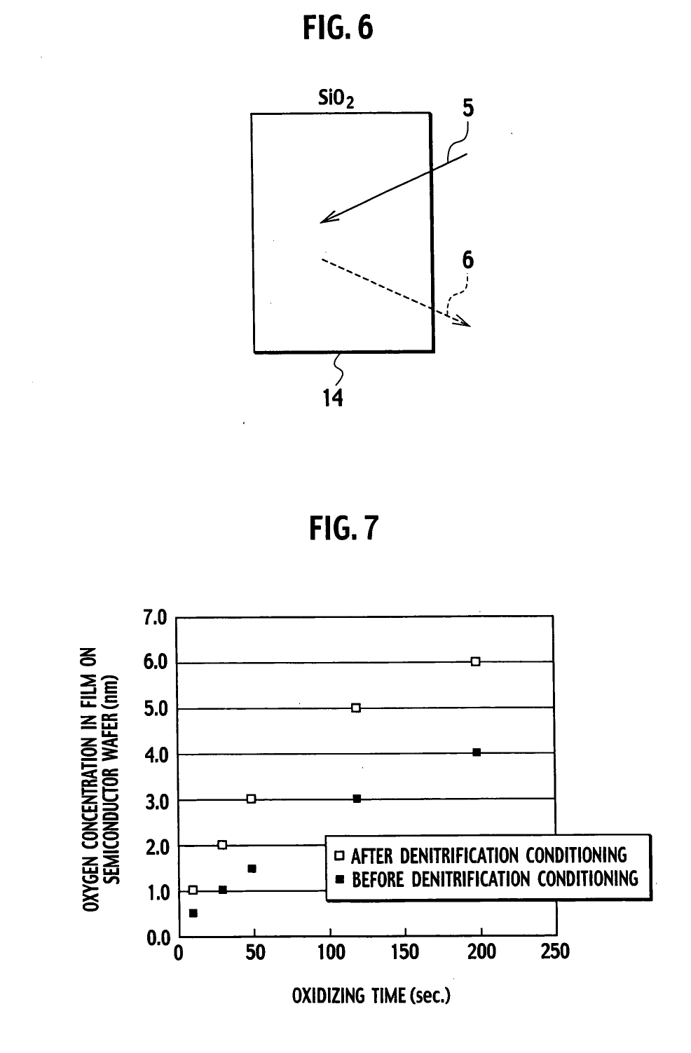

The nitride layer 7, on the surface of the silica cover 14, formed by the nitriding conditioning described above, affects the plasma nitriding process for the untreated substrate 10 that is carried out after the nitriding conditioning, as shown in FIG. 4. The horizontal axis of FIG. 4 represents time required for the plasma nitriding process, and the vertical axis represents nitrogen composition in the nitride film (oxynitride film) formed on the surface of the untreated substrate 10. As shown in FIG. 4, in the case of subjecting the untreated substrate 10 to plasma nitriding for the same duration, the nitrogen composition in the nitride film formed on the untreated substrate 10 is apparently higher when the nitriding conditioning is carried than when such conditioning not carried out.

Accordingly, the nitrogen composition in the nitride film formed on the untreated substrate 10, provided by the plasma nitriding process, may effectively be increased by subjecting the silica cover 14 to the nitriding conditioning. In other words, the time necessary for plasma nitriding the surface of the untreated substrate 10 may be reduced. Furthermore, nitriding conditioning may prevent excessive expenditure of time and money by monitoring the nitride layer 7 on the surface of the silica layer 14. As a result, the nitride film may be efficiently formed on the untreated substrate 10 in a short time, thereby maintaining a stable nitriding rate or film formation rate.

According to the first embodiment, a plasma treatment method is provided that is capable of suppressing changes in a film forming rate and film quality during plasma treatment, and decreases time and cost through a pretreatment by the nitriding conditioning.

(Denitrification Conditioning Method)

A denitrification conditioning method for carrying out a plasma nitriding process for a first lot of substrates and then carrying out a plasma oxidizing process for the next lot of substrates using the plasma treatment apparatus of the first embodiment is described forthwith while referencing the flowchart of FIG. 5. ‘Denitrification conditioning’ is a conditioning process for removal of the nitride layer 7 formed on the silica cover 14 before the plasma nitriding process, which forms a plasma nitride film on the untreated substrate 10.

First, in step S201, a conditioning gas for denitrification conditioning is introduced from the gas inlet 16 to detach nitrogen from the nitride layer 7 on the surface of the silica cover 14, within the chamber 1. Ar gas and O₂ gas are simultaneously introduced into the chamber as the conditioning gas. Gas flow rates of the Ar gas and the O₂ gas are set to be 1000 sccm and 50 sccm, respectively. Once the gas flow rates have stabilized, microwaves are generated from the microwave antenna 15 and then discharged to generate oxygen radicals (O*) The silica cover 14 is then subjected to denitrification conditioning by the oxygen radicals. In this case an internal pressure of the chamber 1 is 130 Pa and the microwave power is 1.0 kW.

While carrying out denitrification conditioning, the surface of the silica cover 14 in the chamber 1 is simultaneously monitored. The monitoring method for the surface of the nitride layer 14 includes measuring the refractive index by exposing the single-wavelength light 5 on the silica cover 14 in the chamber 1 and monitoring the reflected wave 6 with the analyzing unit 20a. Measuring change in the refractive index allows monitoring of changes or detachment of nitrogen from the nitride layer 7 on the surface of the silica cover 14.

In step S202, whether denitrification conditioning has been carried out long enough to eliminate the nitride layer 7 of the silica cover 14 is determined. A signal indicating the thickness of the nitride layer 7 is sent to the control unit 30 from the analyzing unit 20a. If the control unit 30 determines that the nitride layer 7 has been eliminated, processing proceeds to step S203, completing the denitrification conditioning. If the control unit determines that the nitride layer 7 has not been eliminated, processing proceeds to step S204, and denitrification conditioning continues.

Elimination of the nitride layer 7 on the silica cover 14 through the above-described denitrification conditioning affects the plasma oxidizing process carried out after the denitrification conditioning, as shown in FIG. 7. The horizontal axis of FIG. 7 represents the time for the plasma oxidizing process, while the vertical axis represents the thickness of the oxide film formed on the untreated substrate 10. As shown in FIG. 7, in the case of subjecting the untreated substrate 10 to the plasma oxidizing process at the same oxidizing time, the to-be-formed oxide film is apparently thicker when the oxidizing conditioning is carried than when not carried out.

Accordingly, the oxide film formed on the untreated substrate 10, provided by the plasma oxidizing process, may be formed to have a desired thickness in a short time by subjecting the silica cover 14 to the denitrification conditioning. Furthermore, denitrification conditioning may prevent excessive expenditure of time and money by monitoring the nitride layer 7 on the surface of the silica layer 14. As a result, without spending a lot of time for conditioning, the oxide film may be efficiently formed on the untreated substrate 10, thereby maintaining a stable oxidizing rate or film forming rate.

The plasma treatment apparatus of the first embodiment can efficiently carry out nitriding conditioning and denitrification conditioning, thereby improving productivity while maintaining a stable nitriding rate and oxidizing rate, even if the plasma nitriding process and the plasma oxidizing process are carried out by a single apparatus.

According to the first embodiment, a plasma treatment method capable of suppressing changes in film formation rate and film quality during plasma treatment, and preventing expenditure of time and money on the denitrification conditioning method, as a pretreatment, can be provided.

### Second Embodiment

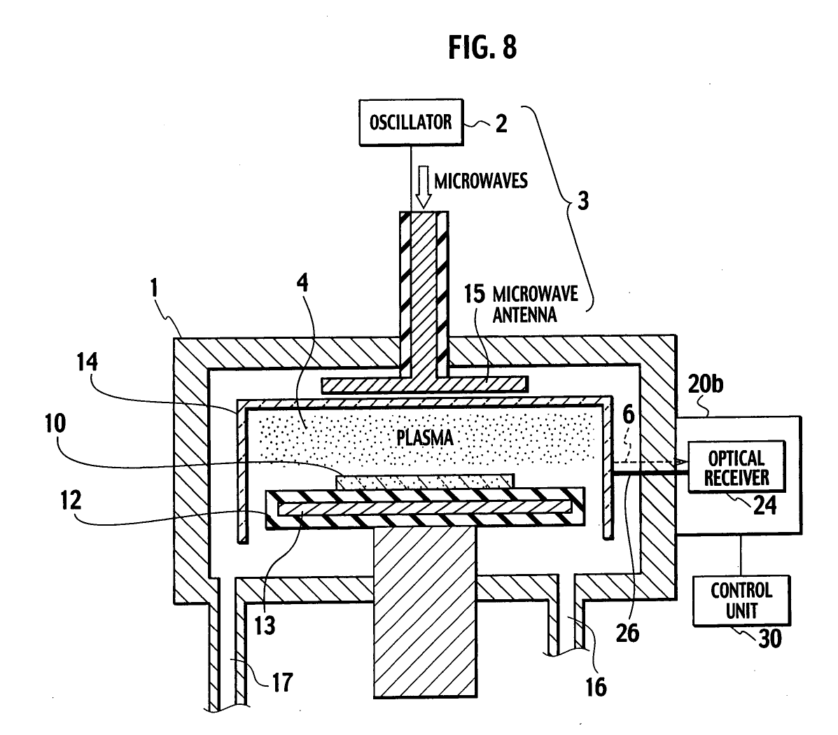

A plasma treatment apparatus according to the second embodiment, as shown in FIG. 8, differs from that of the first embodiment in that an emission spectrum 6, emitted from the surface of the silica cover 14, is monitored by an analyzing unit 20b, in contrast to the analyzing unit 20a for monitoring refractive index of the silica cover 14. The other elements are substantially the same as the plasma treatment apparatus shown in FIG. 1, and thus repetitive description thereof is omitted.

The analyzing unit 20b comprises an optical receiver 24 and an optical transmission line 26. The analyzing unit 20b receives oxygen radicals 4 emitted from the surface of the silica cover 14 and the emission spectrum 6 of the oxygen radicals 4 from the optical receiver 24 via the optical transmission line 26. The radicals being created by the nitriding conditioning and denitrification conditioning. The analyzing unit 20b monitors changes in the nitride layer 7 formed on the surface of the silica cover 14 by measuring changes in the oxygen radicals 4 and optical emission intensity thereof, by the optical receiver 24. Results provided by the analyzing unit 20b are transmitted as a signal to the control unit 30. The nitriding conditioning and the denitrification conditioning are determined to be completed when the oxygen radicals 4 and the emission spectrum 6 of the oxygen radicals 4 have reached a predetermined intensity.

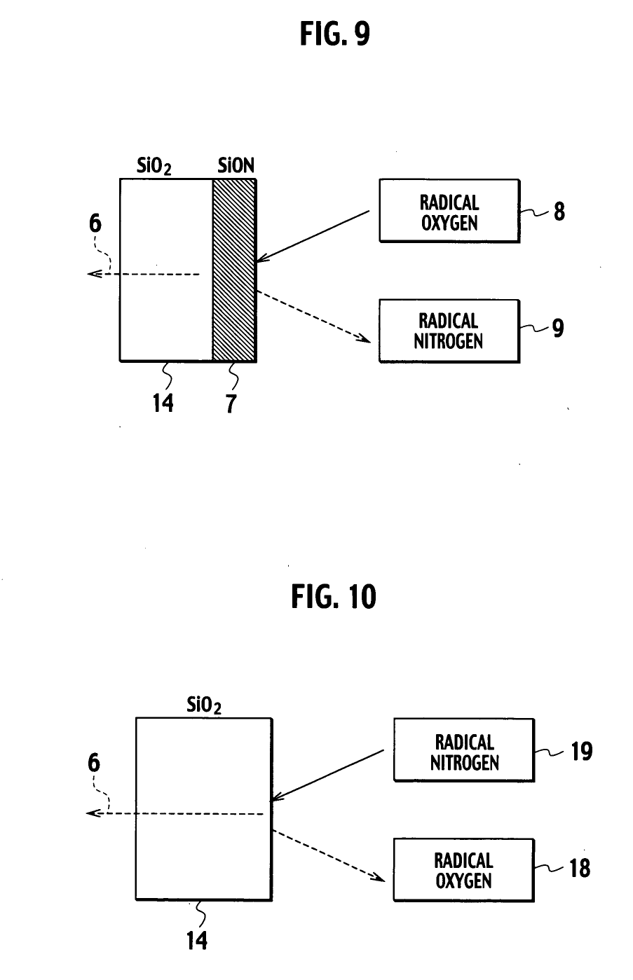

For example, as shown in FIG. 9, with regard to the nitriding conditioning, the radical oxygen 8 reacts with SiON 7, thereby discharging radical nitrogen 9. As shown in FIG. 10, with regard to the denitrification conditioning, the radical nitrogen 19 reacts with SiO₂ 14, thereby discharging radical oxygen 18. The emission spectrum 6 is emitted as the radical oxygen 18 or the radical nitrogen 9 are emitted.

The plasma treatment apparatus of the second embodiment can efficiently carry out nitriding conditioning and denitrification conditioning, thereby improving productivity while maintaining a stable oxidizing rate and nitriding rate, even if the plasma nitriding process and the plasma oxidizing process are carried out by a single apparatus.

According to the second embodiment, a plasma treatment apparatus and a plasma treatment method capable of suppressing changes in film formation rate and film quality during plasma treatment, and preventing expenditure of time and money on conditioning, as a pretreatment, can be provided.

### Third Embodiment

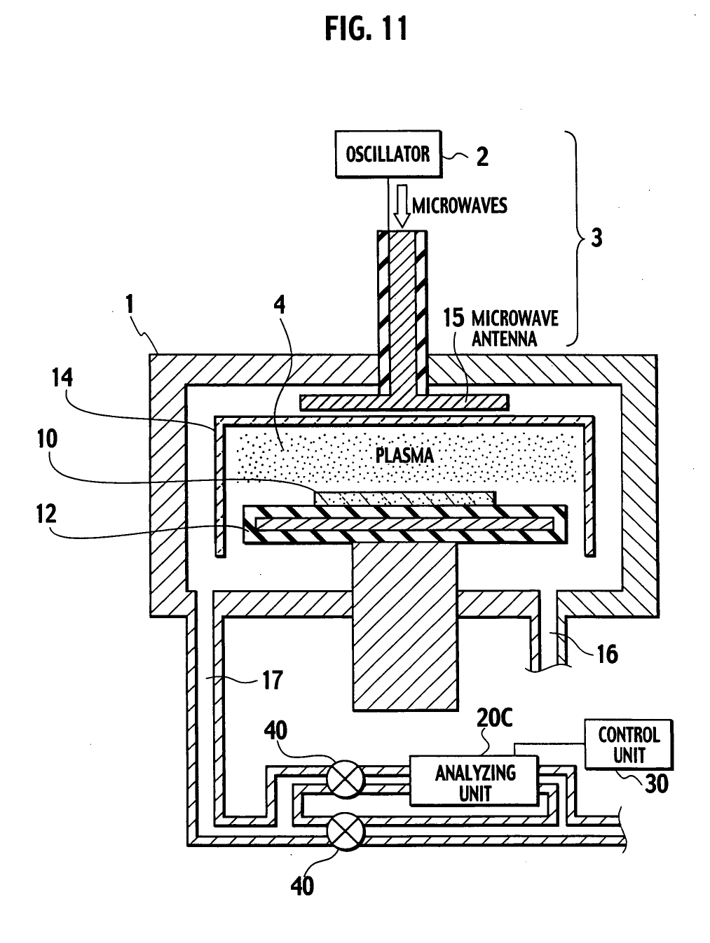

A plasma treatment apparatus according to the third embodiment, as shown in FIG. 11, differs from that of the first embodiment in that, instead of the analyzing unit 20a shown in FIG. 1, an analyzing unit 20c, provided along an exhaust line 17, monitors changes in the nitride layer 7. The other elements are substantially the same as the plasma treatment apparatus shown in FIG. 1, and thus repetitive description thereof is omitted.

The analyzing unit 20c measures the mass of the radical oxygen 18 of FIG. 10 and the radical nitrogen 9 of FIG. 9 within exhaust gas flowing through the exhaust line 17. The gas flow is controlled by valves 40. The analyzing unit 20c is configured to monitor changes in the nitride layer 7, formed on the surface of the silica cover 14, by measuring the mass of the radical oxygen 18 and the radical nitrogen 9. Results provided by the analyzing unit 20c are transmitted as a signal to the control unit 30. The nitriding conditioning and the denitrification conditioning are determined to be complete when the radical oxygen 18 and the radical nitrogen 9 have reached a predetermined mass.

The plasma treatment apparatus of the third embodiment can efficiently carry out nitriding conditioning and denitrification conditioning, thereby improving productivity while maintaining a stable oxidizing rate and nitriding rate, even if the plasma nitriding process and the plasma oxidizing process are carried out by a single apparatus.

According to the third embodiment, a plasma treatment apparatus and a plasma treatment method capable of suppressing changes in film formation rate and film quality during plasma treatment, and preventing expenditure of time and money on conditioning, as a pretreatment, can be provided.

### Other Embodiments

As described above, the present invention is described according to the first through the third embodiment; however, it should not be perceived that descriptions forming part of this disclosure and the drawings are intended to limit the spirit and scope of the present invention. Various alternative embodiments and operational techniques will become apparent from this disclosure for those skilled in the art.

For example, with the plasma treatment apparatus according to the first embodiment, the analyzing unit 20a is described as measuring just the file thickness of the silica cover 14; however, the measurement is not limited to one location, and multiple locations may be measured, alternatively.

Although a semiconductor device has been exemplified above, the present invention need not be limited to the semiconductor device and may naturally apply to fabrication of various electronic devices such as a liquid crystal display, a magnetic storage medium, or a superconducting element.

Note that in the case of a semiconductor fabrication apparatus, the untreated substrate 10, to be subjected to plasma treatment, corresponds to a semiconductor substrate. Alternatively, in the case of a magnetic storage medium, it may be a resin substrate. Moreover, in the case of a superconductive element such as a Josephson device, it corresponds to a superconducting material substrate. Accordingly, the untreated substrate may be any of various materials.

The present invention may be embodied in other specific forms without departing from the spirit or essential characteristics thereof. The embodiments are therefore to be considered in all respects as illustrative and not restrictive, the scope of the present invention being indicated by the appended claims rather than by the foregoing description, and all changes which come within the meaning and range of equivalency of the claims are therefore intended to be embraced therein.

What is claimed is:

1. A plasma treatment apparatus comprising:
a susceptor;
a silica cover covering a plasma generation area located above the susceptor;
a chamber housing the susceptor and the silica cover;
a gas inlet configured to introduce a conditioning gas into the chamber;
a plasma generator configured to generate a plasma of the conditioning gas, and provide a conditioning treatment to the silica cover;
an analyzing unit configured to monitor changes in a nitride layer on the surface of the silica cover; and
a control unit connected to the analyzing unit, and configured to determine completion of the conditioning treatment, based on the changes in the nitride layer.

2. The plasma treatment apparatus of claim 1, wherein the analyzing unit monitors a refractive index of reflected light reflected from the surface of the silica cover.

3. The plasma treatment apparatus of claim 1, wherein the analyzing unit monitors an emission spectrum of radical oxygen and radical nitrogen emitted from the surface of the silica cover.

4. The plasma treatment apparatus of claim 1, wherein the analyzing unit measures the mass of radical oxygen and radical nitrogen in gas exhausted from the chamber.

5. The plasma treatment apparatus of claim 1, wherein the conditioning gas includes nitrogen.

6. The plasma treatment apparatus of claim 1, wherein the conditioning gas includes oxygen.

7. The plasma treatment apparatus of claim 1, wherein an untreated substrate is provided on the susceptor after the conditioning is completed, and the plasma generator generates a plasma and deposits an oxide film on the untreated substrate.

8. The plasma treatment apparatus of claim 1, wherein an untreated substrate is provided on the susceptor after the conditioning is completed; and the plasma generator generates a plasma and deposits a nitride film on the untreated substrate.

9. The plasma treatment apparatus of claim 1, wherein the change in the nitride layer is a change in thickness of the nitride layer.

10. The plasma treatment apparatus of claim 1, wherein the change in the nitride layer is a change in nitrogen composition of the nitride layer.

11. A plasma treatment method including conditioning, said conditioning comprising:
introducing conditioning gas into a chamber housing a susceptor and a silica cover covering a plasma generation area located above the susceptor;
generating a plasma of the conditioning gas by electric discharge for conditioning the silica cover;
monitoring changes in a nitride layer on the surface of the silica cover, based on radicals in the plasma; and
determining completion of the conditioning, based on the change in the monitored nitride layer.

12. The method of claim 11, wherein a reflected light from the surface of the silica cover is detected so as to monitor a refractive index of the nitride layer.

13. The method of claim 11, wherein an emission spectrum of radical oxygen and radical nitrogen emitted from the surface of the silica cover is detected so as to monitor the changes in the nitride layer.

14. The method of claim 11, wherein the mass of radical oxygen and radical nitrogen contained in gas exhausted from the chamber is detected so as to monitor the change in the nitride layer.

15. The method of claim 11, wherein the conditioning gas includes nitrogen.

16. The method of claim 11, wherein the conditioning gas includes oxygen.

17. The method of claim 11, further comprising:
placing an untreated substrate on the susceptor after the conditioning is completed; and
forming an oxide film on the untreated substrate with a plasma generated by the plasma generator.

18. The method of claim 11, further comprising:
placing an untreated substrate on the susceptor after the conditioning is completed; and
forming a nitride film on the untreated substrate by a plasma generated by the plasma generator.

19. The method of claim 11, wherein the change in the nitride layer is a change in thickness of the nitride layer.

20. The method of claim 11, wherein the change in the nitride layer is a change in nitrogen composition of the nitride layer.
